(19) United States
(12) Patent Application Publication
(10) Pub. No.: US 2025/0290968 A1
(43) Pub. Date: Sep. 18, 2025

(54) FAULT DETECTION AND PROTECTION OF BATTERY WITH EXTERNAL FIELD-EFFECT TRANSISTORS

(71) Applicant: Cirrus Logic International Semiconductor Ltd., Edinburgh (GB)

(72) Inventors: Emmanuel A. MARCHAIS, Dripping Springs, TX (US); Brendan T. DEEMS, Austin, TX (US); Qi CAI, Austin, TX (US)

(73) Assignee: Cirrus Logic International Semiconductor Ltd., Edinburgh (GB)

(21) Appl. No.: 19/025,358

(22) Filed: Jan. 16, 2025

Related U.S. Application Data
(60) Provisional application No. 63/566,764, filed on Mar. 18, 2024.

(51) Int. Cl. G01R 31/26; G01R 31/27; H02J 7/00

(52) U.S. Cl. CPC G01R 31/2628; G01R 31/27; H02J 7/00309; H02J 7/0031; H02J 7/0047; H02J 7/0063

(57) ABSTRACT

A system may include sensing circuitry integral to an integrated circuit and configured to sense a voltage and a current associated with a field-effect transistor external to the integrated circuit and control circuitry integral to the integrated circuit and configured to, based on expected relationships between the current and the voltage, control operation of the field-effect transistor.

### RELATED APPLICATION

The present disclosure claims priority to U.S. Provisional Patent Application Ser. No. 63/566,764, filed Mar. 18, 2024, which is incorporated by reference herein in its entirety.

FIELD OF DISCLOSURE The present disclosure relates in general to circuits for electronic devices, including without limitation personal audio devices such as wireless telephones and media players, and more specifically, a battery management system providing protection for a battery cell using external field-effect transistors and fault detection of the battery cell.

### BACKGROUND

Portable electronic devices, including wireless telephones, such as mobile/cellular telephones, tablets, cordless telephones, mp3 players, smart watches, health monitors, and other consumer devices, are in widespread use. Such a portable electronic device may include a battery (e.g., a lithium-ion battery) for powering components of the portable electronic device. Typically, such batteries used in portable electronic devices are rechargeable, such that when charging, the battery converts electrical energy into chemical energy which may later be converted back into electrical energy for powering components of the portable electronic device.

Such devices may include a battery management system, which may be implemented as a battery management integrated circuit (IC), for fuel gauging of a battery. A battery management system may include functionality to detect fault conditions in order to protect one or more cells of the battery. Being able to accurately sense such fault conditions is important so that a protection field-effect transistor (FET) is activated or deactivated at the appropriate or correct times.

External protection FETs may have a thermal limit, expressed either as a power limit or temperature limit. In existing approaches, an optional FET temperature sensor input may be provided to protect a protection FET. However, approaches are desired to protect protection FETs that do not require a dedicated FET temperature sensor.

### SUMMARY

In accordance with the teachings of the present disclosure, one or more disadvantages and problems associated with existing approaches to battery cell protection may be reduced or eliminated.

In accordance with embodiments of the present disclosure, a system may include sensing circuitry integral to an integrated circuit and configured to sense a voltage and a current associated with a field-effect transistor external to the integrated circuit and control circuitry integral to the integrated circuit and configured to, based on expected relationships between the current and the voltage, control operation of the field-effect transistor.

In accordance with these and other embodiments of the present disclosure, a method may include sensing, with sensing circuitry integral to an integrated circuit, a voltage and a current associated with a field-effect transistor external to the integrated circuit. The method may also include based on expected relationships between the current and the voltage, control operation of the field-effect transistor with control circuitry integral to the integrated circuit.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein: FIG. 1 illustrates selected components of an example battery system, in accordance with embodiments of the present disclosure; FIG. 2A illustrates example waveforms of selected physical electrical quantities within the example battery system of FIG. 1 relating to detection of a gate fault of a protection FET, in accordance with embodiments of the present disclosure;

FIG. 2B illustrates example waveforms of selected physical electrical quantities within the example battery system of FIG. 1 relating to detection of a gate fault of a protection FET, in accordance with embodiments of the present disclosure;

FIG. 2C illustrates example waveforms of selected physical electrical quantities within the example battery system of FIG. 1 relating to detection of a gate fault of a protection FET, in accordance with embodiments of the present disclosure;

FIG. 3A illustrates an example waveform of a voltage signal driven to a gate terminal of a protection FET within the example battery system of FIG. 1 relating to detection of a gate fault of a protection FET, in accordance with embodiments of the present disclosure;

FIG. 3B illustrates an example waveform of a current signal resulting from the voltage signal, in accordance with embodiments of the present disclosure;

FIG. 4 illustrates selected components of an example battery system with detail of thermal limit control functionality, in accordance with embodiments of the present disclosure; and

FIG. 5 illustrates selected components of an example battery system with detail of alternative thermal limit control functionality, in accordance with embodiments of the present disclosure.

### DETAILED DESCRIPTION

FIG. 1 illustrates selected components of an example battery system 5, in accordance with embodiments of the present disclosure. As shown in FIG. 1, battery system 5 may include a battery pack comprising fuel gauge block 10, protection FET block 30, and battery 40. The battery pack may be coupled to a charger and may power a load 60.

The battery pack may have an exposed positive voltage terminal VpackP to which the charger and load 60 may be coupled. An internal node of battery voltage VbatP may be coupled at the output of battery 40.

Battery 40 may include any system, device, or apparatus configured to convert chemical energy stored within battery 40 to electrical energy. For example, in some embodiments, battery 40 may be integral to a portable electronic device, and battery 40 may be configured to deliver electrical energy to components of such portable electronic device. Further, battery 40 may also be configured to recharge, in which it may convert electrical energy received by battery 40 into chemical energy to be stored for later conversion back into electrical energy. As an example, in some embodiments, battery 40 may comprise a lithium-ion battery. As shown in FIG. 1, battery 40 may include a cell 42 coupled in series with a sense resistor 44 having a resistance Rsns.

Protection FET block 30 may include a pair of protection FETs comprising a series combination of a discharging (DSG) FET 32 and a charging (CHG) FET 34 coupled between positive voltage terminal VpackP and positive battery terminal VbatP. DSG FET 32 may control discharging of battery 40 and may prevent discharging when DSG FET 32 is off. CHG FET 34 may control charging of battery 40 and may prevent charging when CHG FET 34 is off.

A fuel gauge comprising fuel gauge block 10 may sense a battery current Isns flowing through sense resistor 44, a voltage Vbat_sns across cell 42 (e.g., Vbat_sns=VbatP−VbatN), and/or a battery pack voltage Vpack across terminals of the battery pack (e.g., Vpack=VpackP−VpackN), in order to monitor state of cell 42 and to control operation of CHG FET 34 and DSG FET 32 through a FET driver controller 20. The fuel gauge May 30 also monitor a drain-to-drain voltage VDD on an electrical node common to CHG FET 34 and DSG FET 32.

FET driver controller 20 may include a charge CHG FET control block 24 and a discharge DSG FET control block 22. CHG FET control block 24 may receive sense current Isns as an input and may control operation of CHG FET 34, including activating (e.g., turning on, closing, enabling, etc.), deactivating (e.g., turning off, opening, disabling, etc.), and regulating (e.g., performing linear control of) CHG FET 34. Similarly, DSG FET control block 22 may control operation of DSG FET 32, including activating and deactivating DSG FET 32.

Analog-to-digital converters (ADCs) 50 may convert the various monitored parameters from the analog domain to the digital domain. A fault detection block 55 of the fuel gauge, which may be implemented using digital logic, may perform fault detection based on one or more of such monitored parameters. For example, fault detection may include detection of electrical shorts and partial electrical shorts between the gate terminals of DSG FET 32 and CHG FET 34 to any of positive battery pack voltage terminal VpackP, positive battery cell voltage terminal VbatP, and ground voltage. Fault detection by fault detection block 55 may also include detection of electrical opens or partial electrical opens between the output of FET driver controller 20 and gate terminals of external FETs in protection FET block 30. Fault detection by fault detection block 55 may additionally include detection of electrical shorts between the source and drain terminals of CHG FET 34, shorts between the source and drain terminals of DSG FET 32, electrical shorts between the source terminals of CHG FET 34 and DSG FET 32, electrical shorts between the source terminal of CHG FET 34 and ground, electrical shorts between the source terminal of DSG FET 32 and ground, electrical shorts between the drain terminal of CHG FET 34 and ground, and/or electrical shorts between the drain terminal of DSG FET 32 and ground.

Detection of respective fault detections by fault detection block 55 may identify and classify the type of fault, that is, identifying the location of the fault (e.g., gate, source, or drain node of CHG FET 34 or DSG FET 32), the type of fault (e.g., electrical short or electrical open), and a severity of the fault (e.g., an electrical short that leads to an unsafe condition or a partial short that may not result in an unsafe condition but may still yield an abnormal condition). In some embodiments, classification of a fault may assume that in battery system 5, only a single fault to a single node occurs at a time.

Fault detection and classification by fault detection block 55 may use expected relationships between sensed current Isns and voltages sensed at nodes of CHG FET 34 and DSG FET 32 to determine whether a fault exists. Such relationships may describe an impedance (e.g., voltage divided by current), a power (e.g., voltage multiplied by current), or a logical relationship between ranges of expected values of the current and voltage. For example, during normal charge or discharge operation, FET driver controller 20 may cause both DSG FET 32 and CHG FET 34 to activate, and a source-to-source voltage (VSS) between the source terminal of DSG FET 32 and the source terminal of CHG FET 34 (e.g., VSS=VpackP−VbatP) should be very low. Thus, fault detection block 55 may detect a fault if source-to-source voltage VSS is greater than a predetermined threshold (e.g., |VSS|>100 mV).

As another example, at end of charge of battery 40, FET driver controller 20 may deactivate CHG FET 34 while DSG FET 32 may remain fully activated. Thus, because charging current into battery 40 in this state should be near zero, fault detection block 55 may detect a fault if fault detection block 55 senses a charging current (e.g., if Isns>1 μA where positive Isns indicates a charging current). When battery 40 supplies a discharge current, FET driver controller 20 may activate CHG FET 34 and source-to-source voltage VSS should be small. Thus, fault detection block 55 may detect a fault if it senses a discharge current (e.g., Isns<−10 mA) and source-to-source voltage VSS is greater than a threshold voltage (e.g., |VSS|>100 mV). Further, if positive battery pack voltage VPackP is less than positive battery cell voltage VbatP, then discharge current should flow from battery 40. Accordingly, fault detection block 55 may detect a fault if positive battery pack voltage VPackP is less than positive battery cell voltage VbatP (e.g., VpackP<VbatP−50 mV) and no discharge current is sensed (e.g., Isns>−100 μA).

As an additional example, during a linear charge mode, FET driver controller 20 may deactivate DSG FET 32 and may regulate CHG FET 34 to control an amount of charge current flowing into battery 40. In such state, DSG FET 32 should conduct a charge current through its diode, and source-to-source voltage VSS should be greater than a diode voltage drop. Thus, in such state, fault detection block 55 may detect a fault if positive battery pack voltage VPackP differs from positive battery cell voltage VbatP by more than a diode drop voltage (e.g., VpackP<VbatP+0.6V).

The foregoing faults are non-limiting examples of faults that may be detected by fault detection block 55, and fault detection block 55 may be configured to detect other faults based on a sensed current, one or more sensed voltages, and/or the drive states of DSG FET 32 and CHG FET 34. For example, in some embodiments, an exhaustive list of faults may be simulated to determine a list of conditions that identify and classify a fault based on sensed voltage, sensed current, and/or the drive states of DSG FET 32 and CHG FET 34.

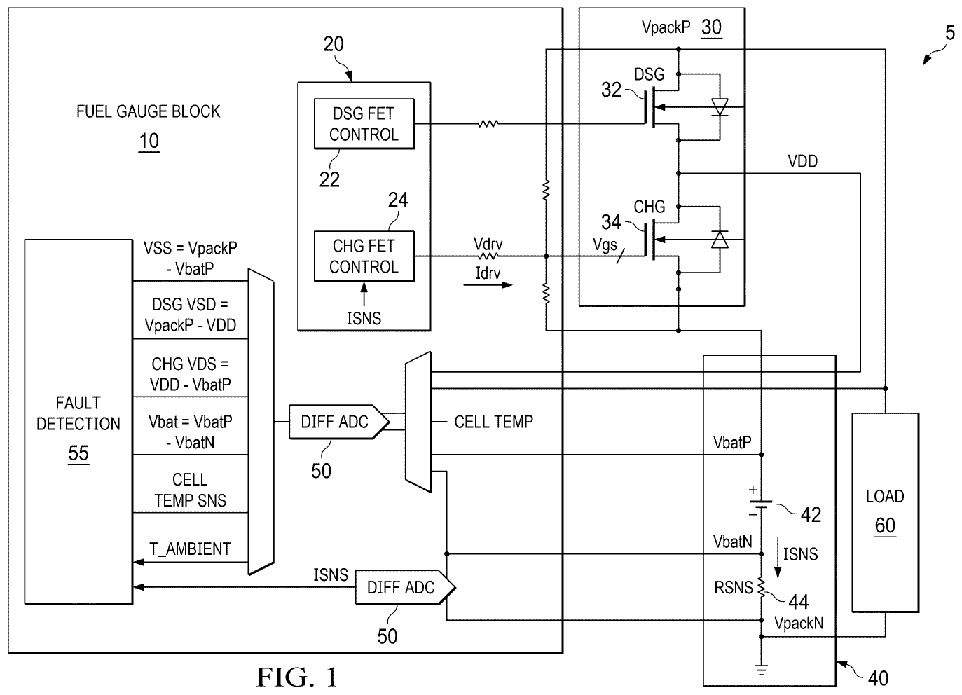

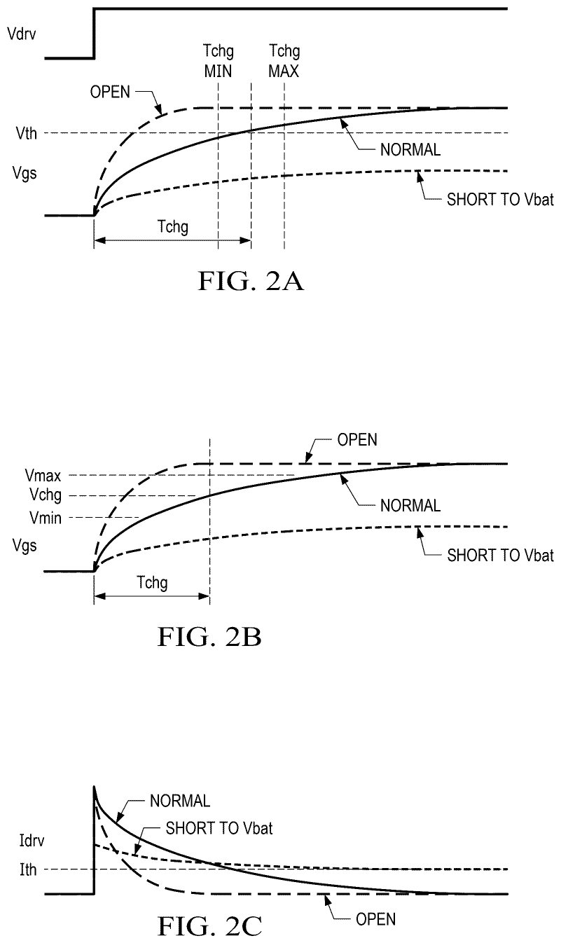

To illustrate other faults detectable by fault detection block 55, reference is made to FIGS. 2A-2C.

FIG. 2A illustrates example waveforms of a driving voltage Vdrv driven by a driver of CHG FET control block 24 and a gate-to-source voltage Vgs of CHG FET 34 relating to detection of a gate fault of CHG FET 34, in accordance with embodiments of the present disclosure. In some embodiments, fault detection block 55 may monitor driving voltage Vdrv and gate-to-source voltage Vgs. When a mode transition occurs to transition

CHG FET 34 from a deactiviated state to an activated state, as shown in FIG. 2A by driving voltage Vdrv increasing from a low voltage to a high voltage, impedance seen by the output of the driver of CHG FET control block 24, the charging time Tchg that it takes gate-to-source voltage Vgs to reach a threshold voltage Vth may be set by the magnitude of driving voltage Vdrv and a time constant related to such impedance (e.g., a time constant equal to an output resistance of the driver multiplied by the gate capacitance of CHG FET 34). However, an electrical open or electric short condition on the gate terminal of CHG FET 34 changes the impedance seen by the driver. Thus, any deviation of charging time outside of a predetermined range may indicate an electrical open or electric short. For example, if charging time Tchg is less than a minimum threshold for charging time Tchg, fault detection block 55 may determine that an electrical open has occurred for the gate terminal of CHG FET 34. As another example, if charging time Tchg is greater than a maximum threshold for charging time Tchg, fault detection block 55 may determine that an electrical short has occurred for the gate terminal of CHG FET 34.

FIG. 2B illustrates an example waveform for gate-to-source voltage Vgs demonstrating an alternative approach for detection of a gate fault of CHG FET 34, in accordance with embodiments of the present disclosure. In the approach of FIG. 2B, fault detection block 55 may test gate-to-source voltage Vgs at fixed time Tchg after the transition of driving voltage Vdrv. If gate-to-source voltage Vgs is greater than a maximum threshold for source-to-gate voltage Vgs at fixed time Tchg, fault detection block 55 may determine that an electrical open has occurred for the gate terminal of CHG FET 34. On the other hand, if gate-to-source voltage Vgs is lesser than a minimum threshold for source-to-gate voltage Vgs at fixed time Tchg, fault detection block 55 may determine that an electrical short has occurred for the gate terminal of CHG FET 34.

FIG. 2C illustrates an example waveform for gate-to-source voltage Vgs demonstrating another alternative approach for detection of a gate fault of CHG FET 34, in accordance with embodiments of the present disclosure. In the approach of FIG. 2C, a driver current Idrv may be monitored to detect existence of a fault. Either time-based test (similar to FIG. 2A) or current-level test (similar to the voltage-level test of FIG. 2B) relating to when driver current Idrv reaches a threshold current Ith may be used by fault detection block 55 to detect, classify, and identify a fault.

While the approaches illustrated in FIGS. 2A-2C and described above contemplate detecting a fault on the gate terminal of CHG FET 34, similar approaches may be used for detecting a fault on the gate terminal of DSG FET 32. For example, instead of using charging times, charging voltages, charging current, and respective charging thresholds, approaches for fault detection on the gate terminal of DSG FET 32 may involve monitoring of charging times, discharging times, voltages, current, and respective thresholds on such gate terminal.

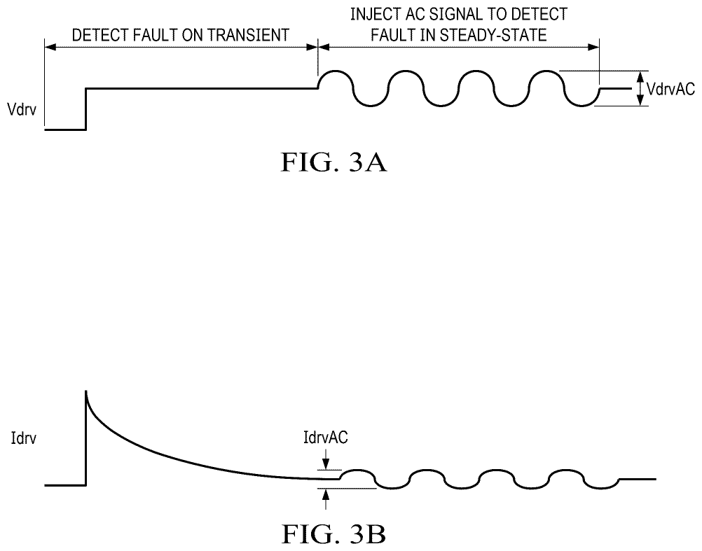

In some instances, on-off transitions of CHG FET 34 or DSG FET 32 may be infrequent, such that the approaches of FIGS. 2A-2C may not be sufficient. Accordingly, in some embodiments, FET driver controller 20 may occasionally drive a small alternating-current (AC) signal comprising one or more frequencies on top of the direct-current (DC) signal, to allow fault detection block 55 to detect an AC output impedance seen at the output of a driver of FET driver controller 20. As shown in FIG. 3A, the driver may drive output voltage Vdrv as a combination of a driver voltage DC component VdrvDC and a driver voltage AC component VdrvAC, such that Vdrv=VdrvDC+VdrvAC. In turn, fault detection block 55 may sense driver output current Idrv, which may be a combination of a driver current DC component IdrvDC and a driver current AC component IdrvAC, and estimate an AC impedance Zout seen by the driver (e.g., Zout=VdrvAC/IdrvAC). If the estimated AC impedance Zout deviates from an expected impedance by a predetermined tolerance factor, fault detection block 55 may determine a fault has occurred. An alternative approach may include analyzing the relationship between driver voltage AC component VdrvAC and driver current AC component IdrvAC in the time domain to determine if a fault has occurred.

In response to a fault event, fault detection block 55 may take an appropriate fault detection action. Example fault detection actions may include, without limitation: disabling protection FETs (e.g., DSG FET 32, CHG FET 34) when possible (i.e., may not be possible if protection FET is shorted), trigger one or more fuses in series with the protection FETs, log the event (e.g., in a non-volatile memory), activate a secondary protector for battery system 5, and signal to the host of battery system 5 a message of the error source and/or communicate a suggestion to disconnect the charger until the battery pack is replaced.

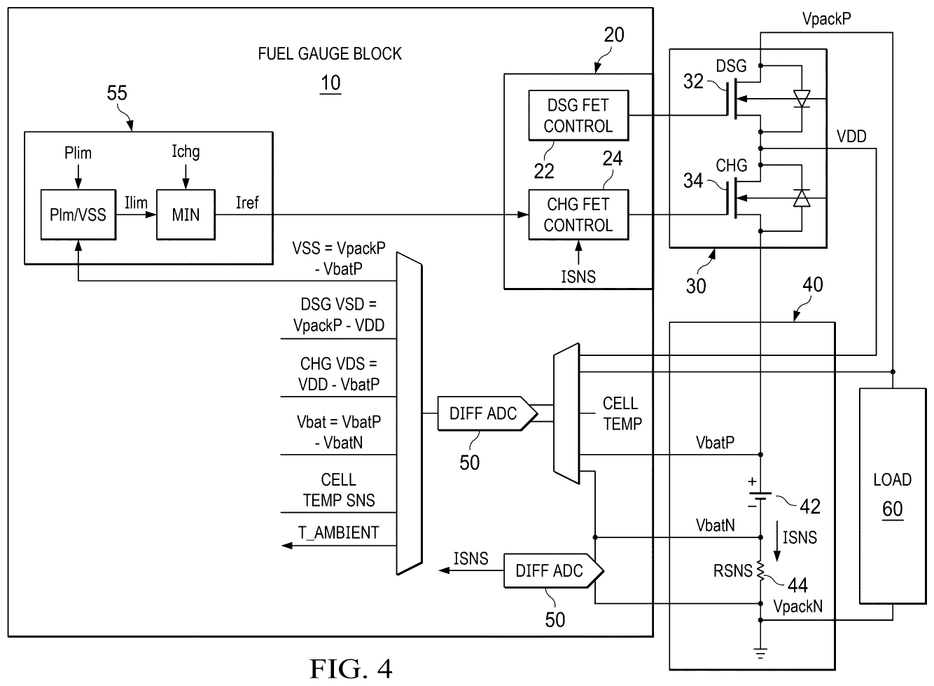

In addition to or in lieu of the foregoing, fault detection block 55 may also protect protection FETs from exceeding their rated thermal limits, as shown in FIG. 4. For example, in a feedback loop (which may operate at approximately 1 kHz to approximately 10 kHz in some embodiments), fault detection block 55 may sense source-to-source voltage VSS across DSG FET 32 and CHG FET 34. Based on such sensed source-to-source voltage VSS and a power limit Plim for DSG FET 32 and/or CHG FET 34 (e.g., as set forth in a device datasheet setting forth specifications of DSG FET 32 and/or CHG FET 34), fault detection block 55 may calculate a current limit Ilim to ensure operation below the power limit (e.g., Ilim=Plim/VSS). Fault detection block 55 may then set a reference current IRef for driving a gate of the protection FET equal to a minimum of current limit Ilim and a user programmed charge current Ichg.

The goal of such feedback loop may be to charge battery 42 at a relatively low current (e.g., less than 1 A) by linearly controlling CHG FET 34. A risk may exist in which if the drain-to-source voltage across CHG FET 34 is too large during the linear charge operation, CHG FET 34 may dissipate too much power, and exceed its rated limit (e.g., 0.5 W−2.0 W). However, fault protection block 55 may reduce the linear charge current to protect CHG FET 34.

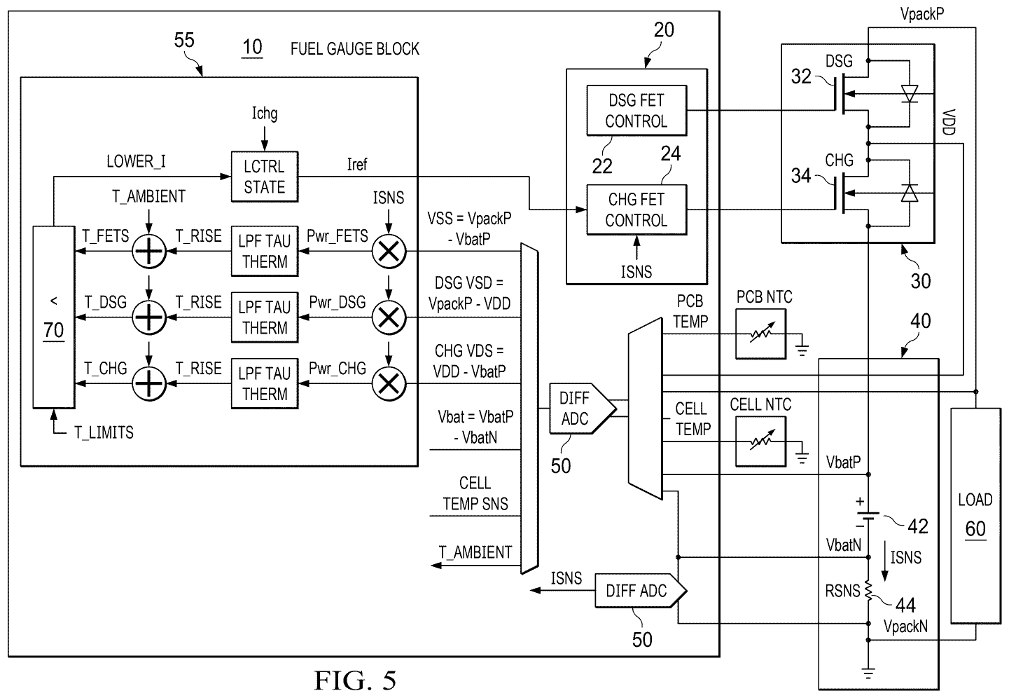

As another example, as shown in FIG. 5, in a feedback loop (which may operate at approximately 1 kHz to approximately 10 kHz in some embodiments), fault detection block 55 may estimate a power dissipation Pwr_FETs from protection FETs as the product of source-to-source voltage VSS and sensed current Isns (e.g., Pwr_FETs=VSS×Isns). Fault detection block 55 may apply a low-pass filter to estimate a temperature rise T_rise of the protection FETs based on power dissipation Pwr_FETs and a characterized thermal time constant Tau_Therm. Fault detection block 55 may then estimate the temperature T_FETs of the protection FETs as equal to the sum of an ambient temperature T_ambient and temperature rise T_risc (e.g., T_FETs=T_ambient+T_rise). Ambient temperature

T_ambient may be derived from another sensor that is a proxy for the ambient temperature, such as a sensor on a printed circuit board comprising the protection FETs or a sensor proximate to battery cell 42. If a comparator 70 of fault detection block 55 determines that the estimated temperature T_FETs exceeds a temperature limit (e.g., such as that set forth in a datasheet for the protection FETs), then fault detection block 55 may request CHG FET control block 24 to reduce a reference current Iref below a user-programmed current value Ichg by an amount of current lower_I.

Because CHG FET 34 and DSG FET 32 may be separate components or may lead to separate thermal hot spots if integrated within the same integrated circuit, individual limits may be added for each protection FET by sensing drain-to-drain voltage VDD to derive the individual current limits in a manner similar to that described above. If drain-to-drain voltage VDD is not available, individual drain-to-source voltages of CHG FET 34 and DSG FET 32 may be based on a charging mode and sensed source-to-source voltage VSS (e.g., based on whether the particular protection FET is activated or whether it is conducting current through its diode having a diode voltage drop).

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
sensing circuitry integral to an integrated circuit and configured to sense a voltage and a current associated with a field-effect transistor external to the integrated circuit; and
control circuitry integral to the integrated circuit and configured to, based on expected relationships between the current and the voltage, control operation of the field- effect transistor.

2. The system of claim 1, wherein the expected relationships describe one or more of an impedance associated with the field-effect transistor, a power associated with the field-effect transistor, or a logical relationship between ranges of expected values of the current and voltage.

3. The system of claim 1, wherein the control circuitry comprises fault detection circuitry configured to:
determine whether a fault exists with respect to the field-effect transistor based on the expected relationships between the current and the voltage; and
responsive to determining the fault exists, execute a fault detection action.

4. The system of claim 3, wherein the fault includes an electrical open or an electrical short associated with the field-effect transistor.

5. The system of claim 3, wherein the fault detection circuitry is further configured to classify the fault.

6. The system of claim 5, wherein classifying the fault comprises classifying a type of the fault.

7. The system of claim 6, wherein classifying the type of the fault comprises identifying the type of fault as either an electrical open or an electrical short.

8. The system of claim 5, wherein classifying the fault comprises classifying a location of the fault.

9. The system of claim 8, wherein classifying the location of the fault comprises classifying the location as being associated with a particular terminal or terminals of the field-effect transistor.

10. The system of claim 5, wherein classifying the fault comprises classifying a severity of the fault.

11. The system of claim 3, wherein the fault detection action comprises one or more of:
disabling the field-effect transistor;
triggering one or more fuses in series with the field-effect transistor;
logging an event associated with the fault;
activating a secondary protection mechanism for the system;
communicating a message regarding a source of the fault; and
communicating a message recommending disconnection of the system from other circuitry.

12. The system of claim 1, wherein the control circuitry comprises thermal control circuitry configured to protect the field-effect transistor from exceeding a rated thermal limit based on the expected relationships between the current and the voltage.

13. The system of claim 12, wherein the thermal control circuitry is configured to protect the field-effect transistor from exceeding the rated thermal limit by limiting the current based on a rated power limit of the field-effect transistor and the voltage.

14. The system of claim 12, wherein the thermal control circuitry is configured to protect the field-effect transistor from exceeding the rated thermal limit by limiting the current based on a rated temperature limit of the field-effect transistor, a power consumed by the field-effect transistor, and a measured ambient temperature associated with the field- effect transistor.

15. The system of claim 1, wherein the system is a battery system further comprising a battery and the field-effect transistor comprises a protection field-effect transistor for protecting the battery.

16. The system of claim 15, wherein the protection field-effect transistor is a charging transistor of the battery system.

17. The system of claim 15, wherein the protection field-effect transistor is a discharging transistor of the battery system.

18. The system of claim 1, wherein the system is a fuel gauge system further comprising a battery and the field-effect transistor comprises a protection field-effect transistor for protecting the battery.

19. A method comprising:
sensing, with sensing circuitry integral to an integrated circuit, a voltage and a current associated with a field-effect transistor external to the integrated circuit; and
based on expected relationships between the current and the voltage, controlling operation of the field-effect transistor with control circuitry integral to the integrated circuit.

20. The method of claim 19, wherein the expected relationships describe one or more of an impedance associated with the field-effect transistor, a power associated with the field-effect transistor, or a logical relationship between ranges of expected values of the current and voltage.

21. The method of claim 19, further comprising, with fault detection circuitry of the control circuitry comprising fault detection circuitry:
determining whether a fault exists with respect to the field-effect transistor based on the expected relationships between the current and the voltage; and
responsive to determining the fault exists, executing a fault detection action.

22. The method of claim 21, wherein the fault includes an electrical open or an electrical short associated with the field-effect transistor.

23. The method of claim 21, further comprising classifying the fault with the fault detection circuitry.

24. The method of claim 23, wherein classifying the fault comprises classifying a type of the fault.

25. The method of claim 24, wherein classifying the type of the fault comprises identifying the type of fault as either an electrical open or an electrical short.

26. The method of claim 23, wherein classifying the fault comprises classifying a location of the fault.

27. The method of claim 26, wherein classifying the location of the fault comprises classifying the location as being associated with a particular terminal or terminals of the field-effect transistor.

28. The method of claim 23, wherein classifying the fault comprises classifying a severity of the fault.

29. The method of claim 21, wherein the fault detection action comprises one or more of:
disabling the field-effect transistor;
triggering one or more fuses in series with the field-effect transistor;
logging an event associated with the fault;
activating a secondary protection mechanism for the system;
communicating a message regarding a source of the fault; and
communicating a message recommending disconnection of the system from other circuitry.

30. The method of claim 19, further comprising protecting, with thermal control circuitry of the control circuitry, the field-effect transistor from exceeding a rated thermal limit based on the expected relationships between the current and the voltage.

31. The method of claim 30, further comprising protecting, with the thermal control circuitry, the field-effect transistor from exceeding the rated thermal limit by limiting the current based on a rated power limit of the field-effect transistor and the voltage.

32. The method of claim 30, further comprising protecting, with the thermal control circuitry, the field-effect transistor from exceeding the rated thermal limit by limiting the current based on a rated temperature limit of the field-effect transistor, a power consumed by the field-effect transistor, and a measured ambient temperature associated with the field-effect transistor.

33. The method of claim 19, wherein the field-effect transistor comprises a protection field-effect transistor for protecting a battery of a battery system.

33. The method of claim 33, wherein the protection field-effect transistor is a charging transistor of the battery system.

35. The method of claim 33, wherein the protection field-effect transistor is a discharging transistor of the battery system.

36. The method of claim 19, wherein the field-effect transistor comprises a protection field-effect transistor for protecting a battery of a fuel-gauge system.
